(19) United States
(12) Patent Application Publication
(10) Pub. No.: US 2012/0256070 A1
(43) Pub. Date: Oct. 11, 2012

(54) NON-LOCKING SUBSTRATE SUPPORT SYSTEM

(76) Inventors: Thomas A. Gordon, Poway, CA (US); Douglas T. Farlow, San Diego, CA (US)

(21) Appl. No.: 13/444,726

(22) Filed: Apr. 11, 2012

Related U.S. Application Data
(60) Provisional application No. 61/474,175, filed on Apr. 11, 2011.

(51) Int. Cl. H05K 7/00

(52) U.S. Cl. 248/310

(57) ABSTRACT

An apparatus that supports substrates that requires no locking of the support members as the support members move up and down and conform to the underside topography of the substrate. The apparatus is especially suited for underside support of printed circuit boards during assembly processes for printing, pick-and-place operations and automated inspection for surface mount style substrates.

### CROSS-REFERENCE TO RELATED APPLICATIONS

This application claims the priority benefit of U.S. Provisional Application Ser. No. 61/474,175, titled “Substrate Support System—Non-Locking,” filed Apr. 11, 2011, the disclosure of which is incorporated herein by reference.

### BACKGROUND OF THE INVENTION

Most processes in the assembly of printed circuit boards require the printed circuit board (PCB) to remain as flat as possible while undergoing operations. This is especially true for PCBs that are designed for surface mount style components.

Typical processes that require flatness are printing, pick-and-place, reflow, and more recently automated optical inspection (AOI).

Virtually all PCB assembly systems, especially the automatic/robotic equipment that have been conveyorized for in-line processing, have lifting tables with support elements added to them. The support elements come in contact with the underside of the circuit board or substrate while both printing solder paste onto the substrate's lands or pads and pick-and-placing components onto the lands and into the solder paste. The support elements eliminate board sag and board bounce that might disturb component placement before reflow operations.

Reflow processes heat the PCB to the point where the solder paste flux burns out and the solder “powder” melts and forms a monolithic solder joint that solders a component's pins/connections to the PCB's lands. AOI equipment requires flatness of the substrate so that the camera elements remain in focus.

Often, substrates have components on both sides and require a second printing, pick-and-place and reflow. Normally, before a first reflow, the underside topography of a printed circuit board is even with the surface of the substrate. When presented with the second side, the topography of the underside of the PCB is varied due to various component heights soldered onto it, and yet even support is still critical for second side operations.

FIG. 1 illustrates a pin and blade support of a substrate according to the prior art. The most common method of supporting PCBs during operations are rigid pins or blades held at a fixed height, placed on the lifting tables, and held in place by mechanical or magnetic means.

FIG. 2 illustrates a pin support conveyor system according to the prior art. When the substrate moves in on the conveyor for a specific operation, it will come to a stop, whereupon the lifting table with its support members will lift into place under the PCB and hold it flat. To facilitate this, these machines have an upper lip as part of the front and rear conveyor rails that grip the substrate along its lateral edges, keeping the PCB from moving upwards beyond a fixed height.

FIG. 3 illustrates another pin support conveyor system according to the prior art. While older systems used the support pins to press the PCB against the upper lip, newer systems have a clamping mechanism embedded in the conveyor that pinch the substrate along its lateral edges and do not rely on the support members to force the PCB against the upper lip. There are other configurations like this that also pinch the substrate against an upper lip without relying on the support pins for this part of the operation. Because the bottom side of the PCB is free of components when operations are initially performed on the top side, it is rather simple to place support members where one desires. It is when the PCB is flipped over for second side operations that it becomes problematic because one then has to locate these fixed height support members at points where components do not exist on the substrate, often leaving large areas unsupported.

The same is also true for printing operations. FIGS. 4 and 5 illustrates another pin support conveyor system according to the prior art. It is necessary that no obstructions protrude above the PCB so that the printing stencil can come into full contact with the substrate. This is often facilitated by having a very thin blade used as the upper lip as shown in FIG. 4, or by the use of snuggers that grip the PCB along its lateral edges as shown in FIG. 5.

For printing operations, it is also necessary that support remain as rigid as possible. The force needed to squeeze paste through the stencil onto the PCB's lands should be sufficient enough to press down any compliant element supported by compressed air or a spring, that is, unless the support pin that comes in contact with the PCB is locked in its final vertical position prior to print. FIG. 6 illustrates stencil length as a function of force. The force typically required is dependent on the length of the squeegee blade used during the printing process and can range from about 3.0 kgf to 11.0 kgf.

Pick-and-place operations are more forgiving in that the force applied during placement of a component is only on the order of 20 gf to 200 gf. Newer compliant nozzle systems will have pre-loaded springs with preloads ranging from 100 gf to 250 gf and final forces of 300 gf to 1200 gf after full compression of the nozzle, respectively. It should be noted, however, that in practice forces are rarely higher than 400 gf. FIG. 7 illustrates the compression spring curves for exemplary compliant nozzles. They are often chosen based on the type of component being placed, and machines can also be programmed to compress the nozzles to the desired placement force. The R&C nozzle is for resistors and capacitors, the SOIC nozzles are for small outline ICs, and the QFP/BGA nozzle are for larger components such as so called Quad-Flat Packs and Ball-Grid Array style components.

While support for printing requires rigidity, pick-and-place operations only need to eliminate board sag and dampen board bounce, substrate support elements needs to be soft and supple at the tip so that components and their pin-outs aren't damaged. This is usually achieved by making the support element material out of a soft material, usually in the durometer range of 60 to 120 on a Shore A scale, or by having the tips of the support element covered with a compliant material in the same durometer range.

In response to this, several types of universal support tooling systems have been developed that will conform to the underside topography of the substrate regardless of whether or not a component has been installed. Their support members move freely up and down when the lifting table is in its upper position and comes into contact with the PCB and will conform to the substrate's topography, whereupon the support members are locked into position before any processes begin. Exemplary of these is U.S. Pat. No.: 5,897,108—Substrate Support System, sold under the brand name “Red-E-Set.”

These systems, however, require the support members to be locked once reaching their desired height (at the substrate's topography), either automatically or manually, which requires set-up and time. As such, it is advantageous to have a universal support tool that does not require locking of the support members, significantly reducing and even eliminating set-up time.

There is a need in the art for an improved substrate support system.

### SUMMARY OF THE CLAIMED INVENTION

The present technology may include a non-locking substrate support system. In the substrate support system, the upwardly biasing element for the support pins may include either a spring, foam, compressed air or the like. For springs and foam, they may follow the generalized formula of Hooke's Law, where the force to compress the biasing element is proportional to the amount of displacement.

Other embodiments of the present technology may not follow Hooke's Law. For example, while compression springs follow Hooke's law, which is linear; conical springs, also known as tapered springs, can be used in lieu of compression springs as an upwardly biasing element. The stress at a given load or deflection (rate) for a tapered spring becomes non-linear once the larger-diameter adjacent coils come in contact with one another during compression. This loss of active coils will cause the tapered spring to become stiffer.

An embodiment of a substrate support system includes a plurality of support pins, a tunnel for each pin, a base member and a foam. Each tunnel allows a pin to travel. The foam is configured to compress upon experiencing a force between an upper surface of the substrate support system and the base member. The foam may be displaced over the pins or between the pins and the base member.

### BRIEF DESCRIPTION OF THE DRAWINGS

FIG. 1 illustrates a pin and blade support of a substrate according to the prior art.

FIG. 2 illustrates a pin support conveyor system according to the prior art.

FIGS. 3-5 illustrate additional pin support conveyor systems according to the prior art.

FIG. 6 illustrates stencil length as a function of force.

FIG. 7 illustrates the compression spring curves for exemplary compliant nozzles.

FIG. 8 illustrates support members with upwardly biasing elements.

FIG. 9 illustrates support member support system using foam placed on top of pins.

FIG. 10 illustrates support member support system using foam and a bladder.

FIG. 11 illustrates support member support system using foam.

FIG. 12A illustrates a graph of force applied over a range of displacement for various foam firmness ratings.

FIG. 12B also illustrates a graph of force applied over a range of displacement for various foam firmness ratings.

FIG. 13 illustrates a graph of pin displacement over time.

FIG. 14 illustrates a graph of Force versus time for various foam firmnesses.

FIGS. 15-19 illustrate graphs of force versus time for various foam firmnesses.

FIG. 20 illustrates a graph of displacement over time.

FIG. 21 illustrates a graph of Direction under Nozzle Load over time.

FIG. 22 illustrates a graph illustrating deflection under nozzle load over support used.

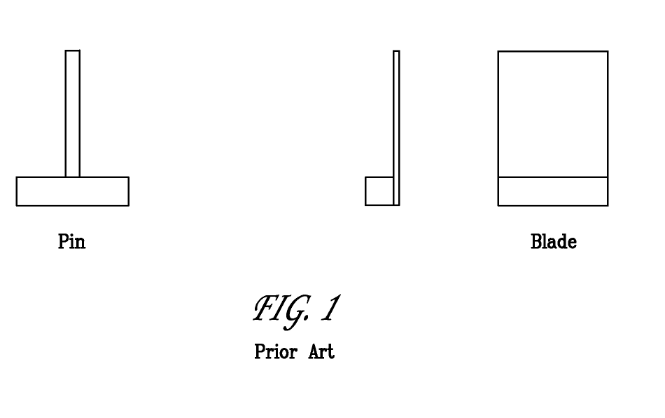

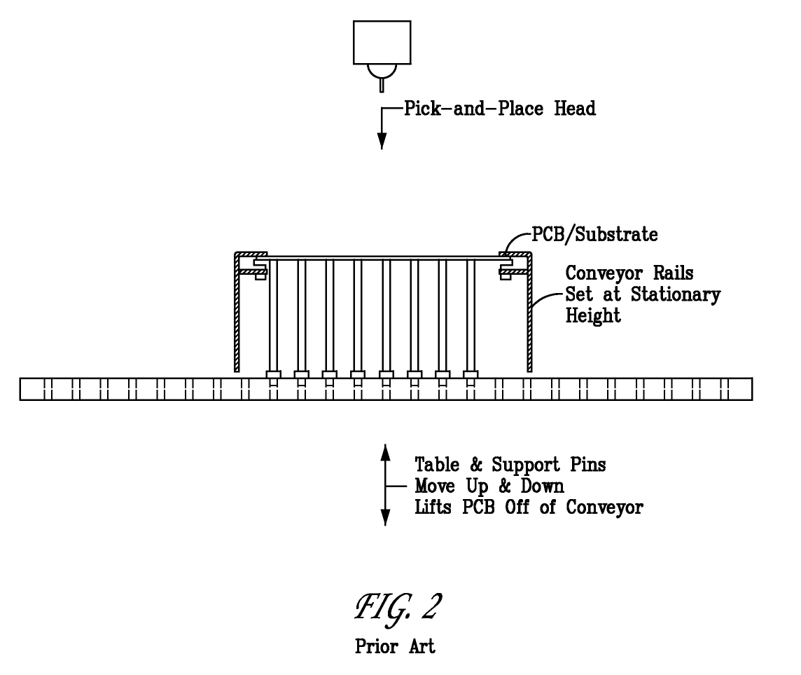

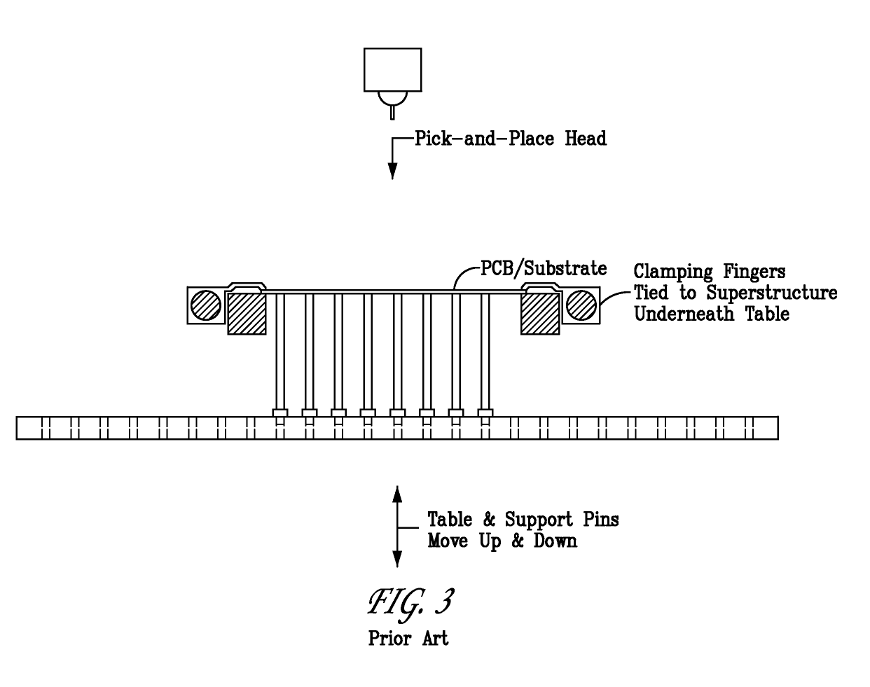

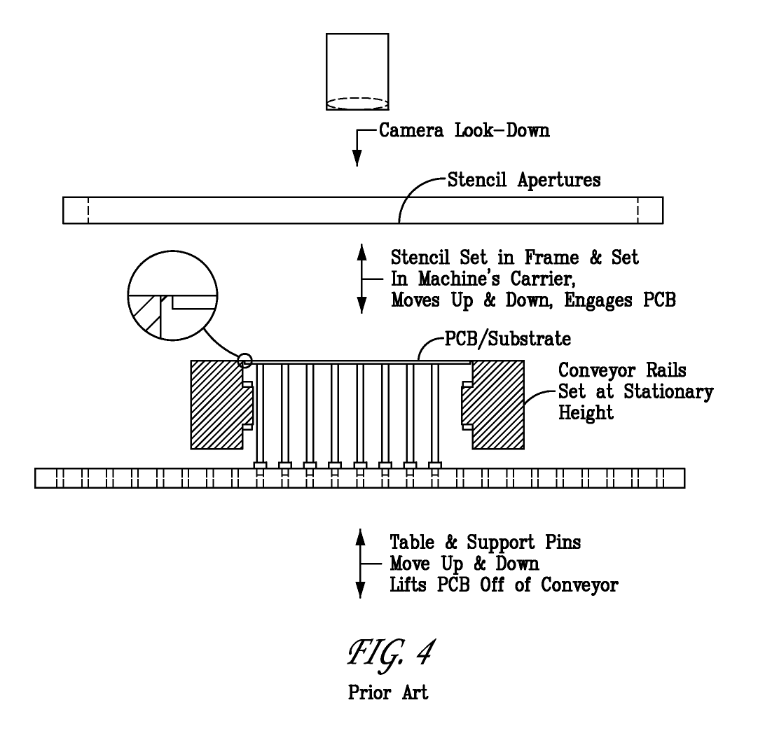

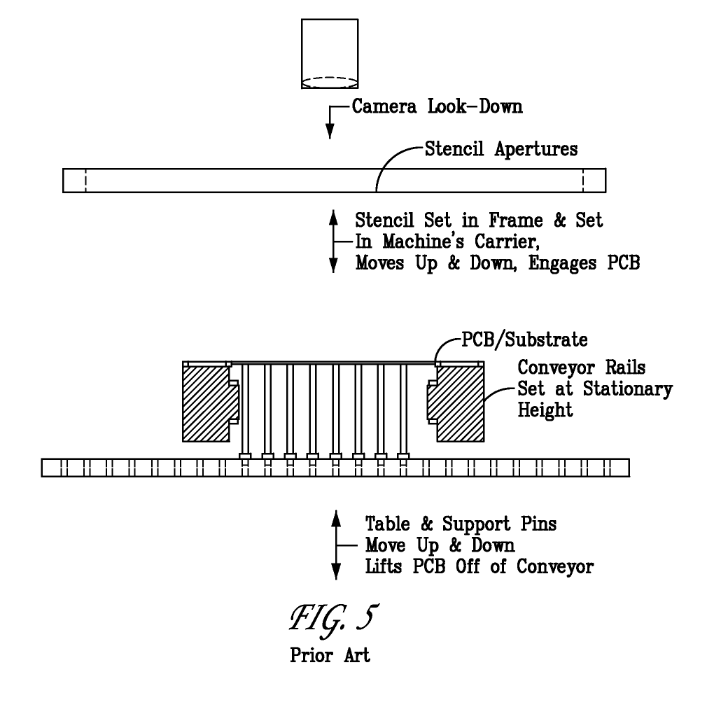

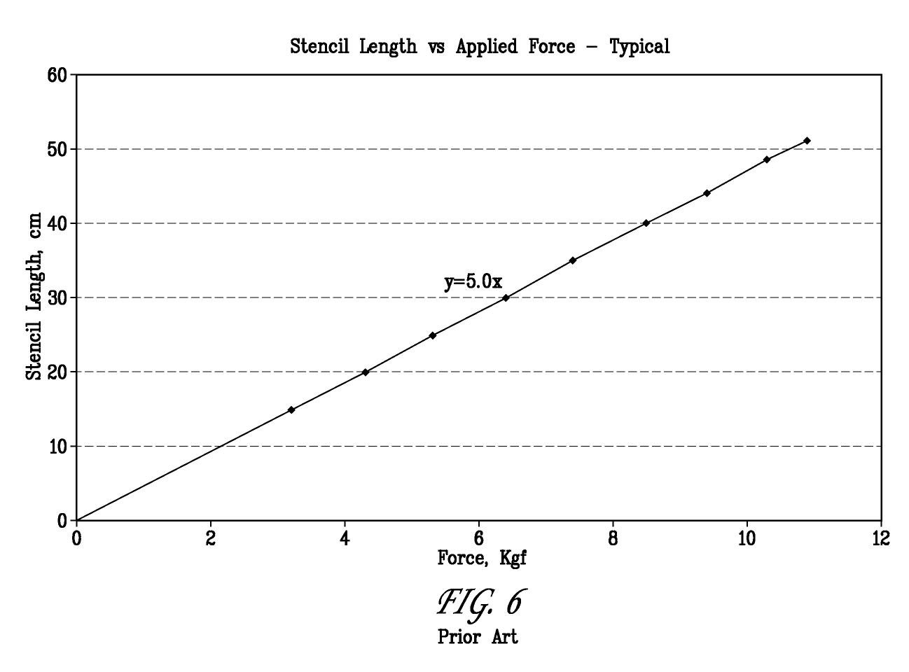

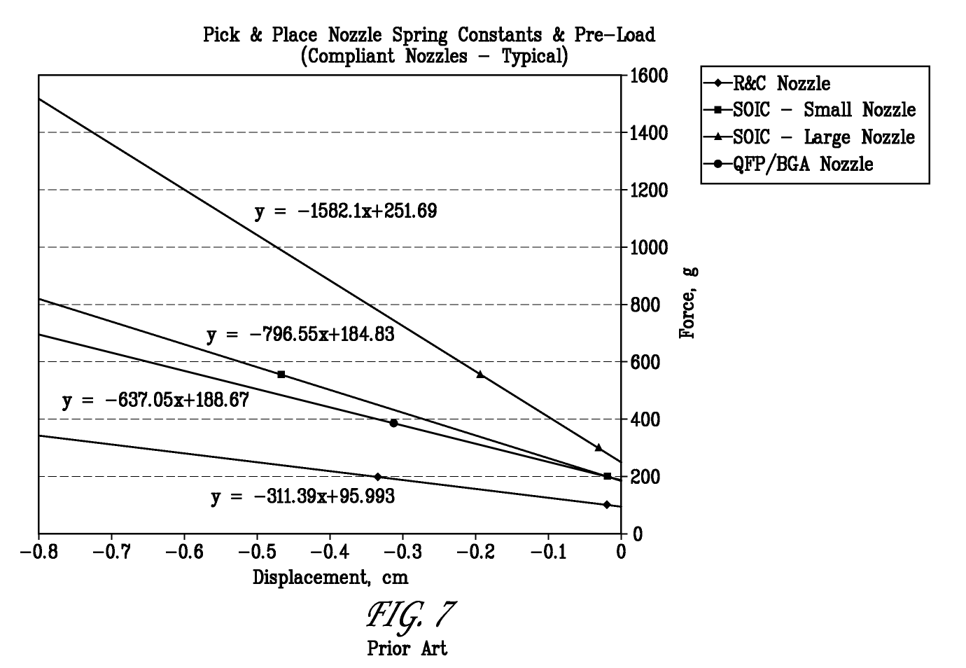

### DETAILED DESCRIPTION

The present technology may include a non-locking substrate support system. In the substrate support system, the upwardly biasing element for the support pins may include either a spring, foam, compressed air or the like. For springs and foam, they may follow the generalized formula of Hooke's Law, where the force to compress the biasing element is proportional to the amount of displacement.

Other embodiments of the present technology may not follow Hooke's Law. For example, while compression springs follow Hooke's law, which is linear; conical springs, also known as tapered springs, can be used in lieu of compression springs as an upwardly biasing element. The stress at a given load or deflection (rate) for a tapered spring becomes non-linear once the larger-diameter adjacent coils come in contact with one another during compression. This loss of active coils will cause the tapered spring to become stiffer. With this in mind, various methods and apparatuses have been investigated to see if dynamic and automatically adjustable support can be achieved. This was especially important for pick-and-place operations, since rigid support is not a rigorous requirement.

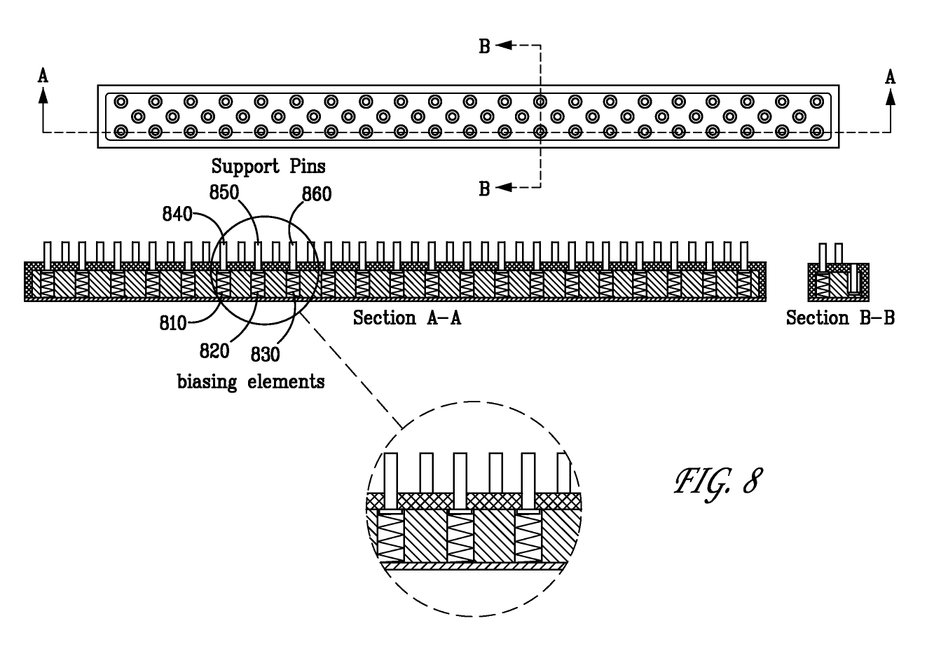

An embodiment of the present invention may use support members in a tool with upwardly biasing elements. FIG. 8 illustrates support members with upwardly biasing elements. The upwardly biasing elements 810, 820 and 830 can be utilized where the support members 840, 850 and 860 were not locked. The biasing elements may be displaced directly or indirectly next to base member 870. If the biasing elements exhibit too much force, it could over-bow the substrate (upwardly). If it had too little force the board could sag (downwardly), and even if the force was exactly where it needed to be, it could still allow too much board bounce and could disturb component placement. Still, and depending on placement forces and component height, this embodiment does have utility, for example if the substrate is merely populated with small passive and active components that require very little placement force and do not over-compress the biasing elements. It should be noted that the upwardly biasing elements in these cases follow the linear curve of Hooke's Law where:

F=−k s

F=Force

k=Spring Constant

s=Displacement

An embodiment of the present invention may use foams in both open cell and closed cell architectures. Closed cell foams exhibit a fairly high spring constant and do not offer the “give” helpful to support substrates, especially ones with tall components soldered onto it. Open cell foams offer the ability to give way to tall components, but it may act spring like and not eliminate board bounce to a level that would not disturb component placement, especially components with high mass.

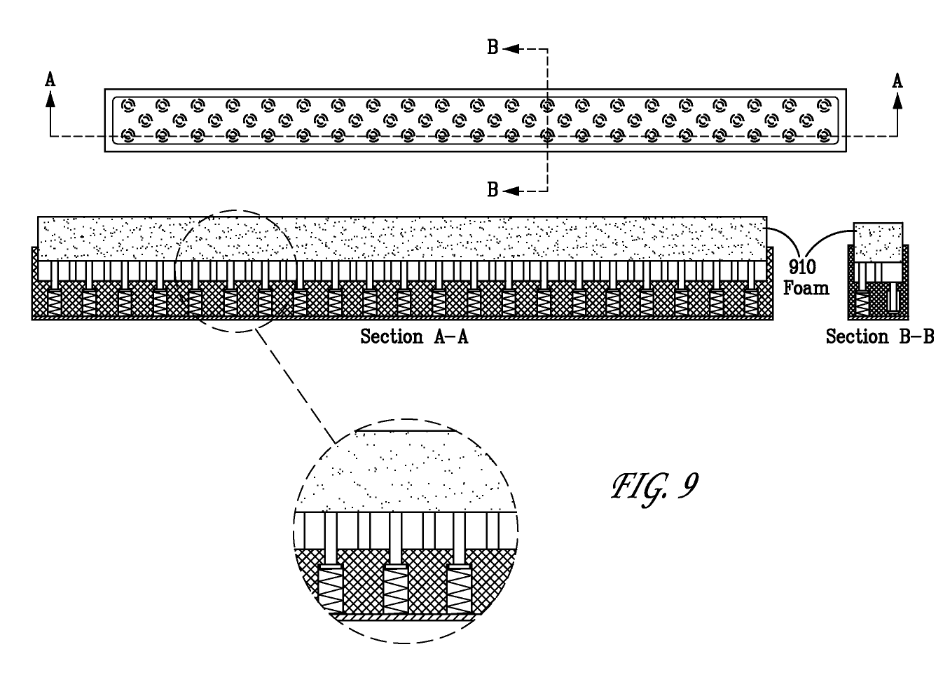

FIG. 9 illustrates support member support system using foam placed on top of pins. An embodiment of the present invention may use foam 910 placed on top of a series of pins 940 with springs 930, much like a mattress on top of box springs. The pins with springs may be displaced directly or indirectly over a base member 920. A thin film of flexible material may be used between the foam and the springs or pins to keep the pins or springs from digging into the foam, but may add a trampoline-like effect, depending on how thick the flexible material was. The pins with springs may

This same set-up may use memory foam, that is an “open-cell” polyurethane foam that can further described as having a “slow-recovery” and is “super-resilient.” This foam does not follow Hooke's Law as will be seen. This arrangement easily gives as required, especially with tall components. It may act trampoline like, although it does perform better than a foam that follows Hooke's Law, and the support might not prevent board bounce except with lighter compliant nozzles where the nozzle forces were under about 150 gf.

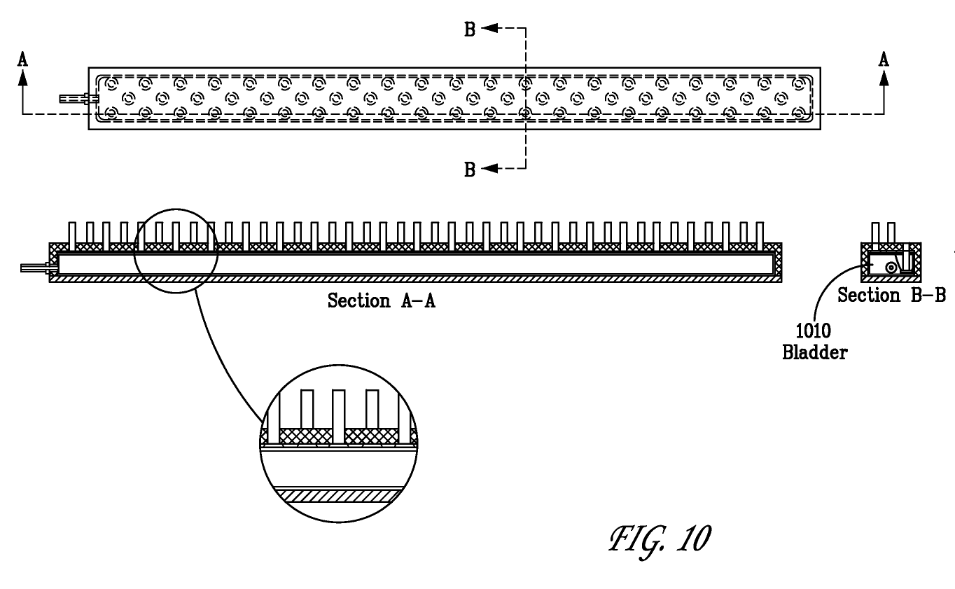

FIG. 10 illustrates support member support system using foam and a bladder. In some embodiments, the support structure of FIG. 8 may be modified by outfitting it with a bladder 1010 that could be filled with pressurized air, hydraulic fluid, or a gel until the support pins met the surface of the substrate without over-bowing the substrate or allowing it to sag. This configuration provides excellent dynamic support; and utilizes a new set-up for substrates of different configurations.

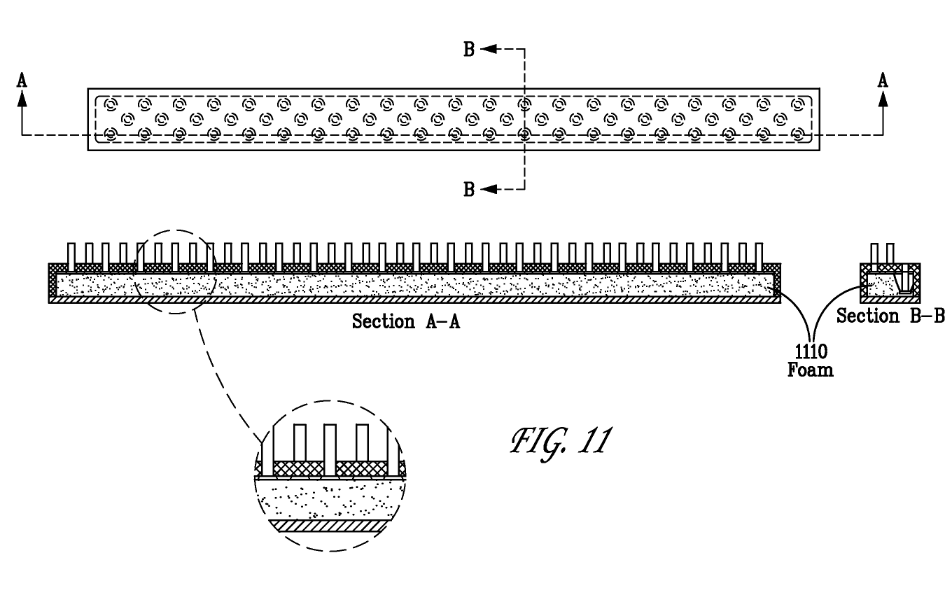

FIG. 11 illustrates support member support system using foam. Memory foam 1110 of certain firmnesses can be used without having to lock the pins into their respective vertical position after having come into contact with the substrate's underside topography. The foam works over a wide range of substrate sizes, thicknesses, and component heights.

In some embodiments, instead of the foam coming into direct contact with the substrate, the body of the support unit that contains the support pins has a hollowed out cavity that contains the foam. The pins ride up and down the holes in the body with the foam underneath providing the necessary upwardly biasing element. The body no longer has a series of plates for locking purposes and instead the top “plate” with its sides and ends only needs a base plate to fully seal the foam and the base of the pins within.

By placing the foam inside the cavity and having pins ride on top of the foam, this configuration eliminates a trampoline effect and individualized each pin's response to the repeated contact with the pick-and-place nozzles.

However, when the lifting table is in its up position and a single pin is sufficiently displaced by a tall component, it can affect pins that directly surround the highly displaced pin, if the surrounding pins are not themselves sufficiently displaced downward. Embodiments of the present invention may address this by pocketing out an area where each support pin has its own individual piece of memory foam that it rides upon, breaking the interconnections of the open cell foam with foam supporting adjacent pins.

Pins can be of varied diameters, heights, material, and durometers and the body that contains them along with the foam can be configured to accommodate the material to maximize substrate coverage and allowable pin displacement. They are typically anti-static or conductive and various materials can be used from thermoplastics to rubbers. Also, stiffer members can be inserted into the pins to stiffen them such as steel dowels; and finally, metal pins can be used that can be covered at its tips with a soft material.

The substrate support unit is completely scaleable in all of its axes. It can be made as long as necessary, as wide as necessary and as tall as necessary. It can also have additional stand-off elements underneath that allow it to reach its required machine specific height and other hardware that allows it to be attached to the machine's specific lifting table. This includes magnets, screws, pins, double-sided tape, etc.

It should be specifically noted that other than placing this system down upon a lifting table, there is no other set-up required.

The firmness of the foam may be chosen based on the size and thickness of the substrate under consideration. A firmer foam might be used with a thicker or smaller board than say a larger or thinner board and vice-versa. At the same time, if a substrate has tall components, softer foams can be used so as to not over-bow the board in the upward direction. Foam stiffness is rated by the manufacturers of the material and includes a numerical value for stiffnesses, with a rating of 1.0, 1.5, 2.0, 3.0 and 4.0, and they are usually color coded. Moreover, the material can be made RoHS compliant and anti-static or conductive.

In general, and according to the manufacturer of the memory foam, the open cell polyurethane foam has high energy absorption properties with an unusually low compression set. This along with its slow recovery allows it to absorb shock and vibration over a range of dynamic loads while maintaining consistent static load performance, and is highly effective in damping and vibration isolation. As such, the foam works differently depending whether or not it is measured under static or dynamic conditions.

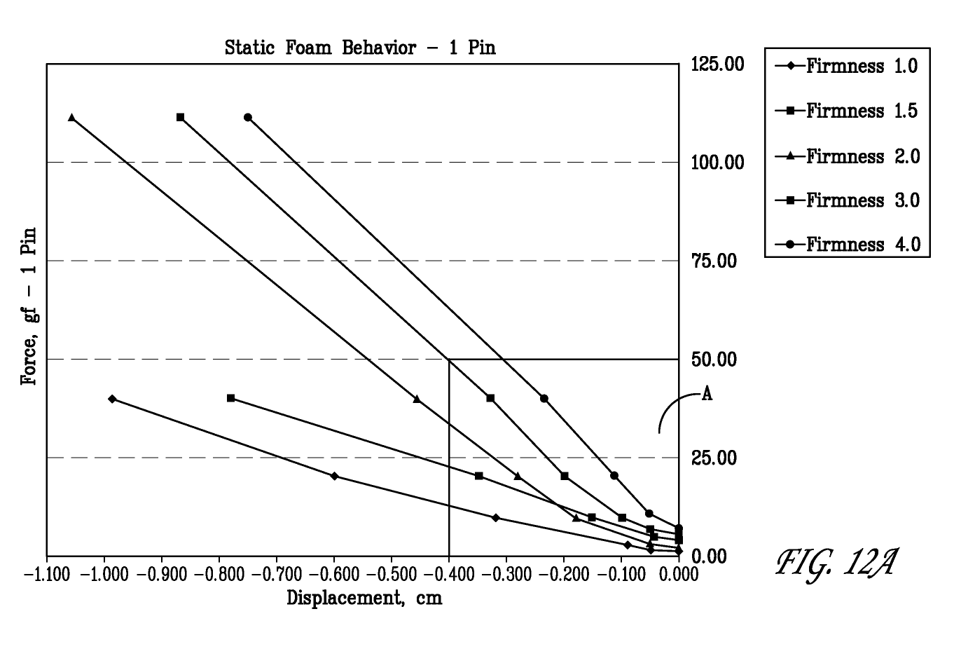

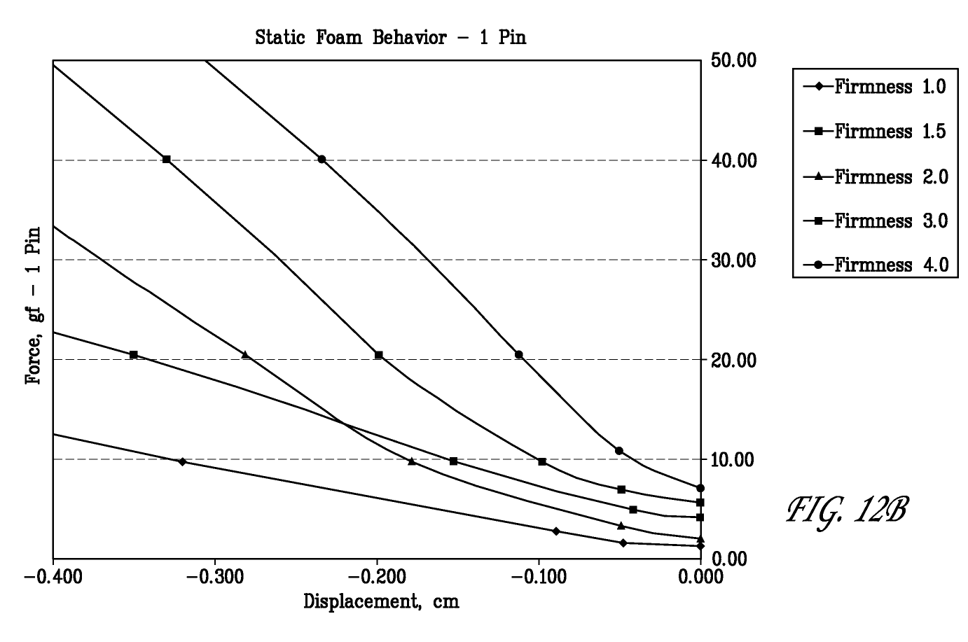

FIG. 12A illustrates force applied over a range of displacement for various foam firmness ratings. Under static conditions, if a load is placed on a support pin and allowed to relax after a period of time, it appears to follow Hooke's Law in that it is uniformly linear except under very light loads. At loads around 10 gf or smaller, depending of the foam's firmness, a natural preload is observed in that the foam will resist giving way at all. FIG. 12B also illustrates force applied over a range of displacement for various foam firmness ratings. FIG. 12B provides more detail for area A of FIG. 12A. It can also be observed that on the low end of this curve, the foam does not behave in a linear fashion. It is not until the foam has about 10 to 15 gf applied to it (depending on its firmness) and allowed to relax that the foam will behave linearly. Dynamically, its behavior is very different.

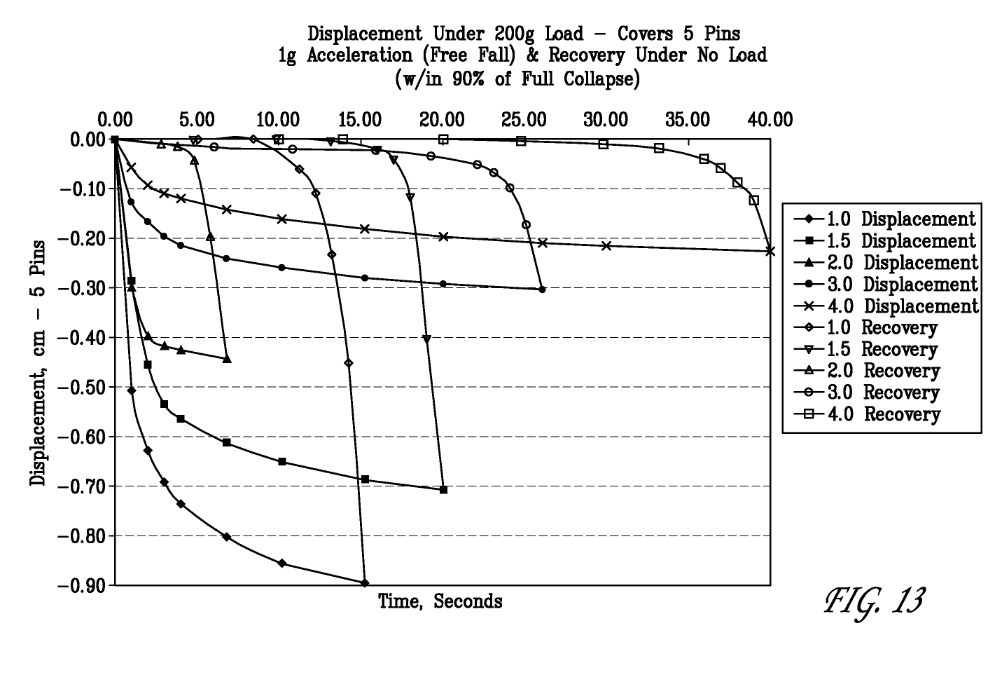

FIG. 13 illustrates pin displacement over time. The graph of FIG. 13 illustrates how the various firmnesses of foam behave when a 200 gf is set upon five (5) support pins. The load is under free fall (1 g of acceleration) and is allowed to come within 90% of its fully relaxed condition. The displacement is shown as a function of time. Upon reaching the relaxed condition, the load is then removed and the foam will push the pins back up to their initial positions. It is interesting to note that the foam has a hysteresis, that is, it does not follow the same path during recovery that it took when under load.

In some embodiments, two main considerations can be addressed when using the foam. The first is lifting table impact, whereupon when the lifting the table rises with the support units placed on top. Where it meets the substrate, care must be taken to minimize the impact forces that are transferred to the substrate and components.

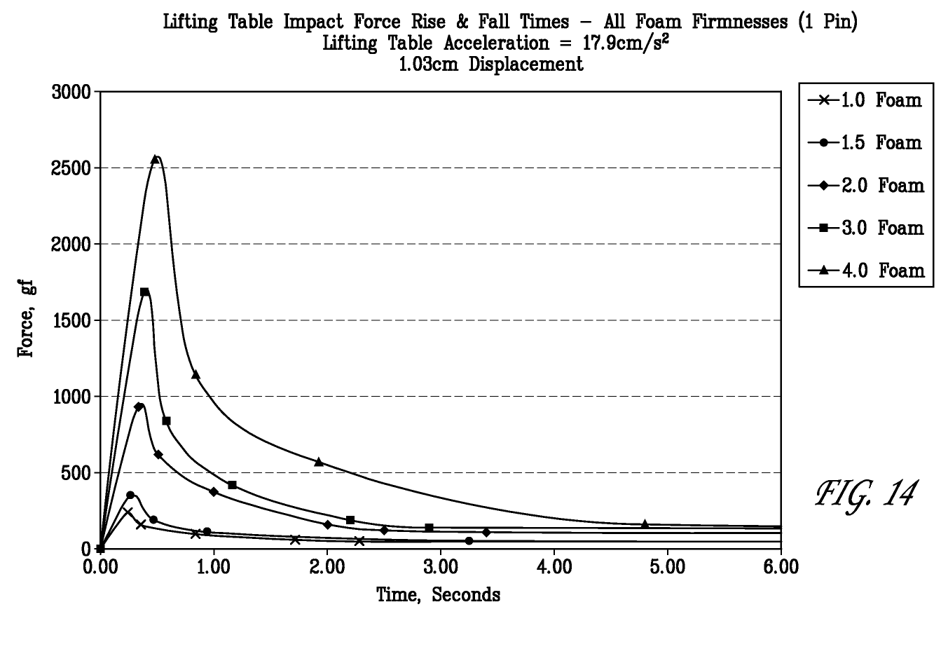

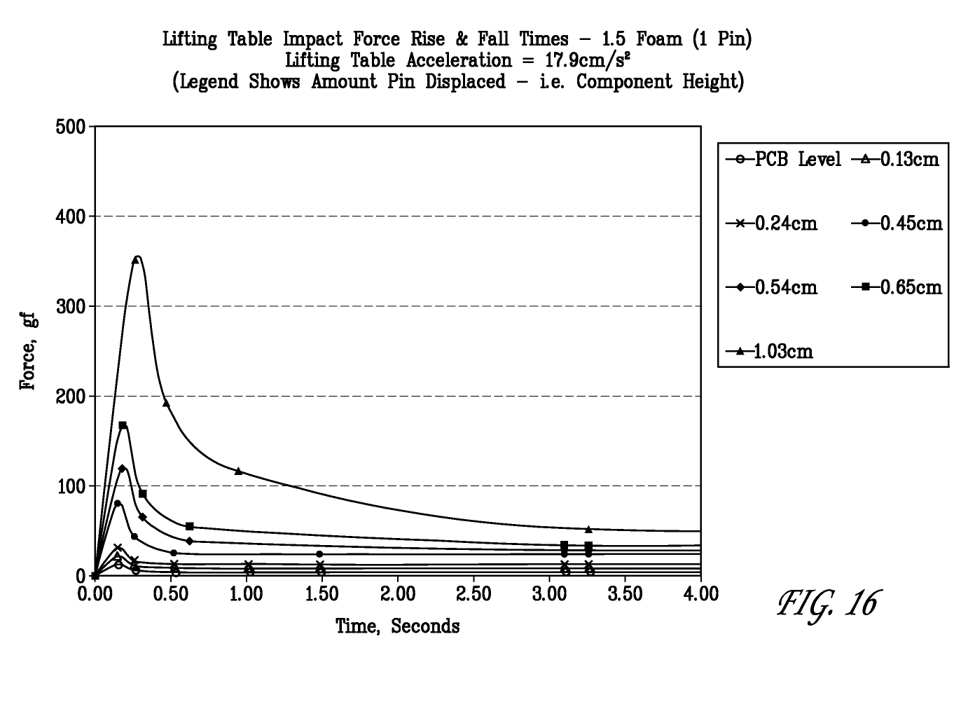

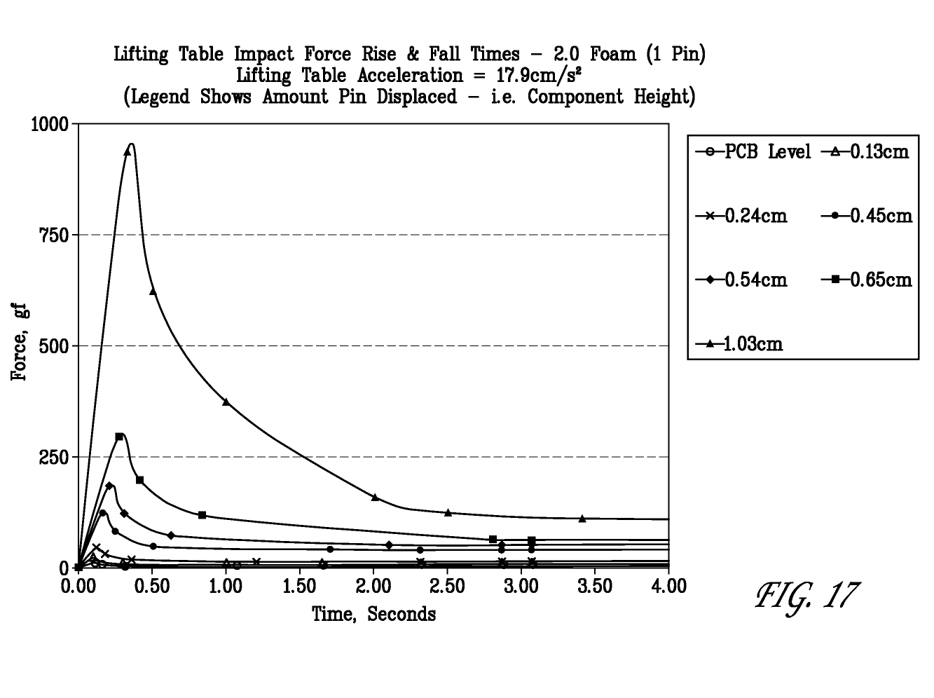

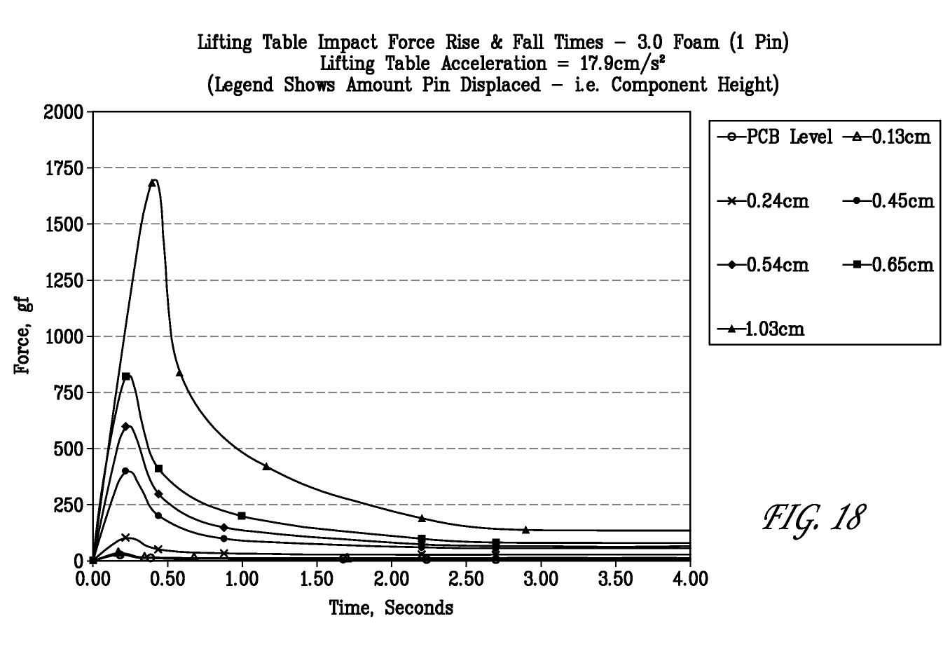

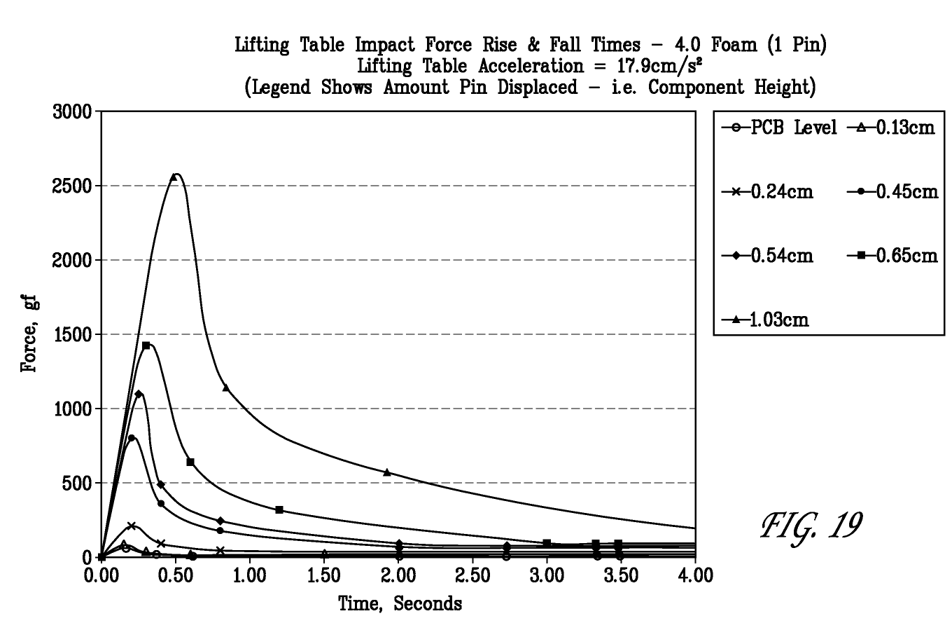

FIGS. 14-19 show how the foam reacts in the substrate support system when placed on a lifting table, and where the table and system rise to meet a substrate with components of various heights on the bottom side of the substrate. These figures show force over the duration that the force is applied until the foam relaxes.

FIG. 14 illustrates a graph of force versus time for various foam firmnesses. The graph of FIG. 14 shows how the forces seen as a function of time appear for the various firmnesses of foam when a single support pin is displaced by approximately one (1) cm and accelerated from its initial position to its final position at 18 cm/s². Other conditions are as follows: The total displacement of the lifting table is 2.5 cm, and the operation occurs in approximately 0.5 seconds, with the initial velocity at 0.0 cm/s, the average velocity at 4.75 cm/s and the final velocity at 9.5 cm/s. The pin, as it is shoved down by the component will initially present a much higher force with the force dramatically falling as the foam relaxes.

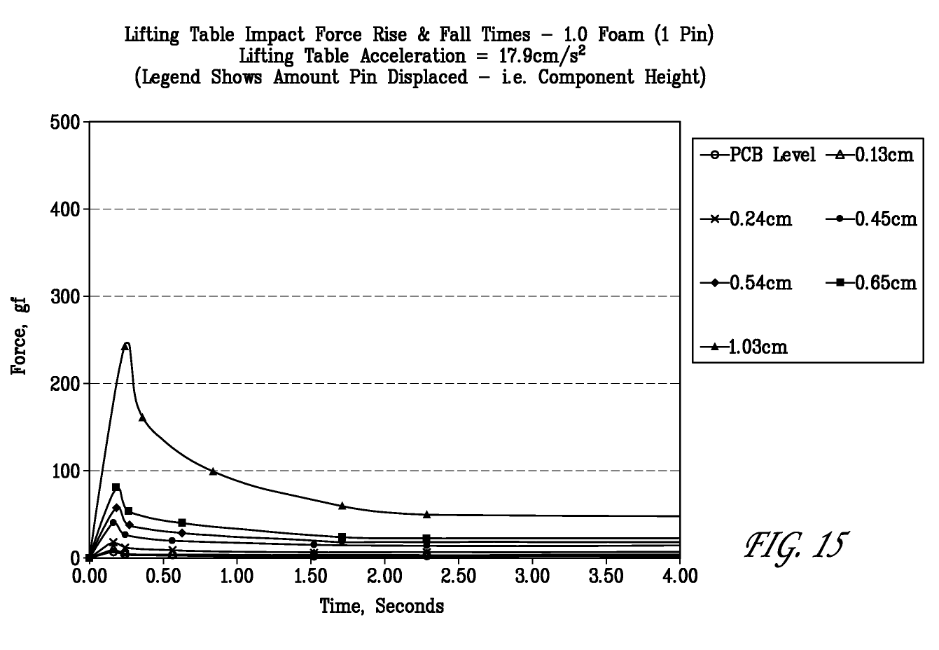

FIGS. 15-19 illustrate graphs of force versus time for various foam firmnesses. An examination of single firmnesses of foam under the same conditions discussed with respect to FIG. 14 above but with various displacements shows that the force is dependent upon how far it is displaced. This initial impact force can also be changed by how fast the lifting table meets the substrate, with a lower speed giving rise to a smaller force and vice versa.

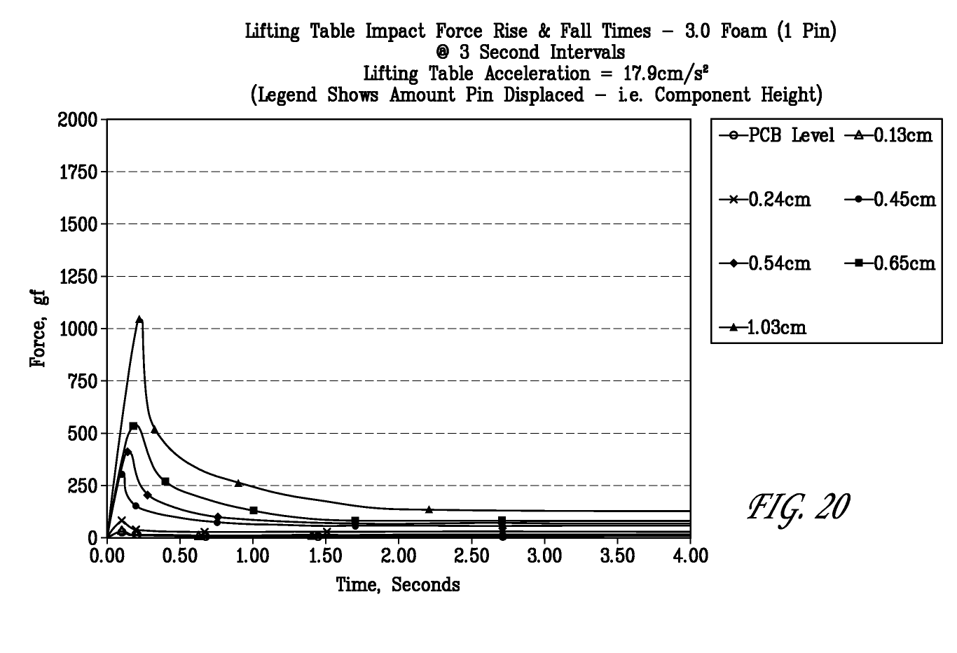

FIG. 20 illustrates a graph of displacement over time. The graph indicates how the foam behaves with impacts at three (3) second intervals. This simulates the forces seen by subsequent substrates as they shuttle into and out of the operation on the conveyor system. Typically, after the operation is performed to a printed circuit board, the lifting table will drop and allow the board to move to the next operation, with additional boards waiting in the queue. This shuttling in and out of substrates takes but a few seconds. This shows the “memory” that the foam has built into it, as it has not fully recovered to its fully extended position and enjoys a predisposed position based on its last relaxed state. This predisposed relaxed impact force is typically about 25% less than an initial peak impact force.

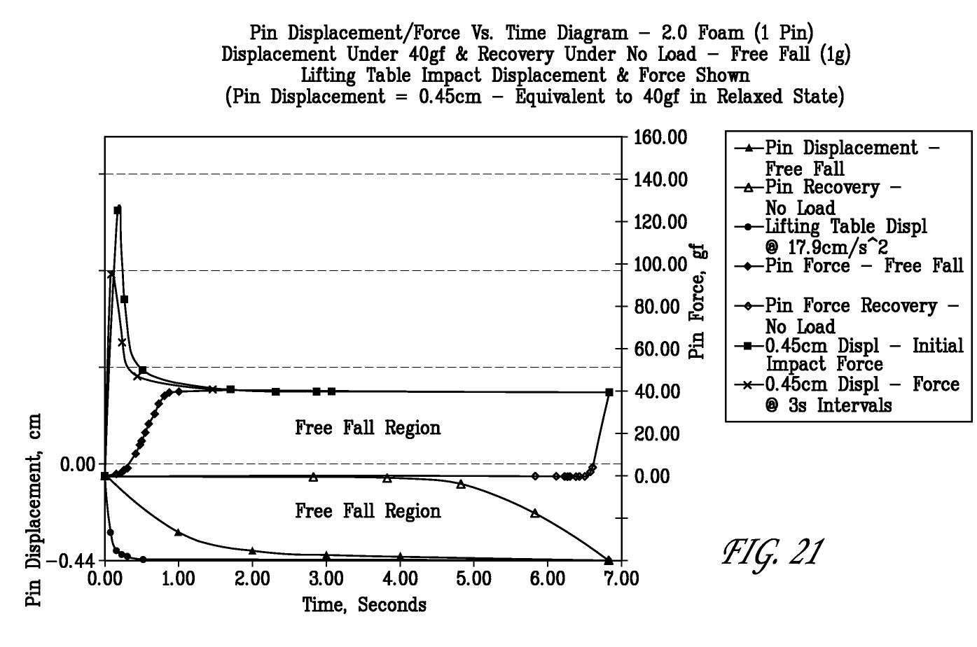

FIG. 21 illustrates a graph of Direction under Nozzle Load over time. FIG. 21 is a composite graph showing how a single firmness of foam (2.0 Firmness in this instance) behaves under a 0.45 cm displacement, both under freefall and with a lifting table acceleration of 18.0 cm/s² as a function of time. The force data is shown above the x-axis with the displacement data shown below the x-axis. It also has superimposed on it the peak force produced at the three (3) second interval—that is, upon subsequent impacts.

If the foam is layered instead of being a monolithic piece (2-ply), the initial peak impact force can be 40 to 45% lower than that of a single monolithic piece, with subsequent impacts at three (3) second intervals still being about 25% less than the initial peak impact of the layered foam, with only about a 5% degradation in the foam's ability to support the substrate under pick-and-place impacts. When the foam is layered with more than two (2) plies, the ability to support the work-piece under pick-and-place impacts may decrease.

It should also be pointed out that in the layering of the foam into more than a single ply, combinations of foam firmnesses can be used to different effects. Also, the foam can be slightly over-stuffed in the foam cavity with little to no effect. The design of the system is such that the base plate of the unit can be rapidly removed for easy changeover of foam firmnesses if necessary. The memory foam also works best at a certain temperature and humidity range. In some embodiments, a temperature range may vary within 65 to 85° F. and 30 to 70% RH. Temperature has the greatest affect in that cold environments will make the foam stiffer while high temperatures will prevent the foam from giving proper support. The range specified, however, is well suited to the work environment often found in printed circuit board assembly operations.

It should also be noted that the foam can tear if presented with sharp edges. The pins that ride on top of the foam have a head on them like a nail to keep them affixed to the body of the unit (see FIG. 11). By radiusing the edge of the head, it can minimize and even eliminate tearing, and this can be further mitigated by knowing how deeply the foam can be compressed repeatedly without tearing (proprietary info). Another way to alleviate any foam tearing is to add a thin film between the foam and the head of the pin (not shown). This film can be made of any material that will give way without bunching up.

The system is typically built with a slight over-travel. Hence, instead of the units being at exactly the machine's specific height requirements a slight over-travel can be built in to ensure the support pins engage the PCB, even if the PCB is slightly bowed upward. At the same time, and depending on unique PCB requirements, this arrangement can be changed to meet each individual application. This is particularly suited for Original Equipment Manufacturers (OEMs) that may only need to build a small number of circuit boards with limited configurations, as opposed to a contract manufacturer that may have hundreds of different board sizes and configurations.

In practice, the foam quickly responds to a downward pressure during lifting table impact. Most of the robotic pick-and-place equipment will error out if the substrate is sagging below 0.5 mm of its flat position or above 0.5 mm of its flat position after it reads the fiducials (targets) on the substrate and tries to perform its first pick-and-place. The foam's firmness can be selected so that it responds quick enough during this brief window (about 1 to 3 seconds) so that the supported substrate is within its required Z-axis tolerance parameter and will eliminate board sag without over-bowing and minimize board bounce.

In some embodiments, the foam works by resisting to giving way, but with a proper firmness selected, it gives way quickly enough to avoid “erroring out” the equipment it is installed on, and will further flatten out as pick-and-place and printing operations commence.

Outside of lifting table impact, the second main consideration is how the substrate reacts to the actual pick-and-place impact. After the foam gives way and settles, it resists giving way any further and will present a higher upward force under pick-and-place impact than would happen under linear spring conditions. Moreover, since it is slow to recover, it is well set up to accommodate and settle into subsequent similar substrates that follow. Each board with any variances in underside part placement from a first reflow will automatically present its specific topography to the foam. Support pins and any deviations in height will be accommodated as the pins are either further forced down or are allowed to rise up. As such, it is impossible for a pocket to form.

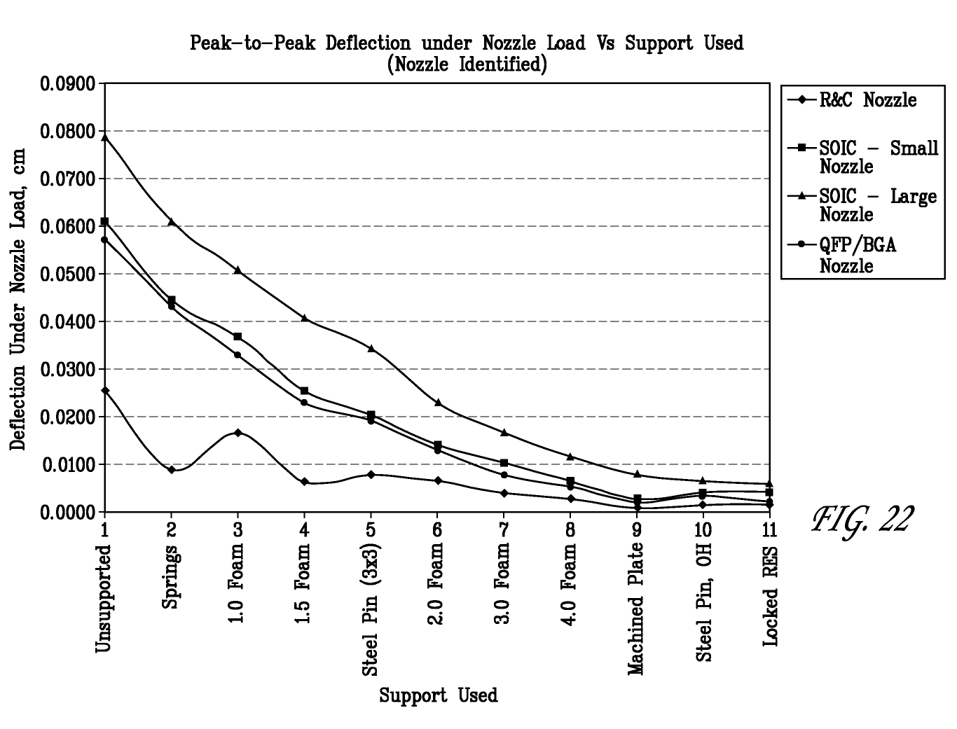

FIG. 22 illustrates a graph illustrating deflection under nozzle load over support used. The graph of FIG. 22 shows how the foam behaves during actual pick-and-place operations. A medium sized PCB (10″×8″) with a 0.059″ thickness is shown under various types of support. The data was obtained using the four (4) pick-and-place nozzles described earlier and operated the nozzles at a pick-and-place rate of 15,000 placements per hour (often called cph—chips per hour).

The graph shows the peak to peak displacement measured when the substrate was unsupported, yet clamped along its lateral edges by the conveyor (all other test also have the PCB clamped at the conveyor). The PCB was supported by support pins with compression springs with a spring constant of 76 gf/cm with the pins allowed to move freely up and down. Five foam firmnesses were presented in the graph of FIG. 22. Embodiments may include the system under standard support pins, one where the pick-and-place action is centered between three standard support pins in an equilateral triangle with three (3) inch sides and one with the pick-and-place action directly overhead of said standard support pin. A conventional plate that provides 100% bottom side support (Often having hogged out cavities to accommodate components for the second side) and with a Red-E-Set that has its pins locked into position.

The present system uses foam and unlocked support elements and perform better than the standard pins in the three (3) inch per side equilateral triangle configuration which has been achieved. That is not to preclude the use of the softer firmnesses of foam, as there can easily be found applications where such foams may have acceptable performance, nor does this preclude developing foams that may be softer or firmer than what was tested.

There are many possible variations on this technology as anyone familiar with the arts will quickly appreciate. Such variations are within the scope of this invention. For instance, so called selective solder applications where miniature solder waves can come up to a PCB from below and solder small regions may require the substrate to be flattened from above and the system can easily be turned upside down to accommodate such an application.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

What is claimed is:

1. A non-locking substrate support system, comprising:
a plurality of support pins;
a tunnel for each pin, the tunnel allowing each pin to travel; and
a base member, each pin configured to travel between an upper surface of the substrate support system and the base member.

2. The non-locking substrate support system of claim 1, further including a conical spring configured to compress upon experiencing a force between an upper surface of the non-locking substrate support system and the base member.

3. The non-locking substrate support system of claim 1, further including a foam configured to compress upon experiencing a force between an upper surface of the non-locking substrate support system and the base member.

4. The non-locking substrate support system of claim 3, wherein the support pins are configured to support the substrate and provide the upper surface, the foam displaced between the base member and each pin.

5. The non-locking substrate support system of claim 3, wherein the foam is displaced above the plurality of support pins.

6. The non-locking substrate support system of claim 1, further including a bladder for absorbing force applied to the pin.

7. The non-locking substrate support system of claim 6, wherein the bladder is displaced between a foam and the base.

8. The non-locking substrate support system of claim 5, further including a spring displaced between each pin and the base.

9. The non-locking substrate support system of claim 8, further including a foam.

10. The non-locking substrate support system of claim 9, further including a thin film of flexible material between the foam and the springs.

11. The non-locking substrate support system of claim 3, wherein the foam has an open cell architecture.

12. The non-locking substrate support system of claim 3, wherein the foam has a closed cell architecture.

13. The non-locking substrate support system of claim 3, wherein the foam has a firmness rating of between 1.0 and 4.0.

14. The non-locking substrate support system of claim 3, wherein the foam is formed from a conductive material.

15. The non-locking substrate support system of claim 3, wherein the foam is formed from a non-static material.

16. The non-locking substrate support system of claim 3, wherein the foam has at least two layers, the first layer having a first firmness and a second layer having a second firmness.
